(19) United States
(12) Patent Application Publication
(10) Pub. No.: US 2026/0156957 A1
(43) Pub. Date: Jun. 4, 2026

(54) SOLID-STATE IMAGING DEVICE

(71) Applicants: TOWER PARTNERS SEMICONDUCTOR CO., LTD., Uozu City (JP); TOWER SEMICONDUCTOR LTD., Migdal Haemek (IL)

(72) Inventors: Toshifumi YOKOYAMA, Uozu City (JP); Yoshiaki NISHI, Uozu City (JP); Akiko KATSUYAMA, Uozu City (JP)

(73) Assignees: TOWER PARTNERS SEMICONDUCTOR CO., LTD., Uozu City (JP); TOWER SEMICONDUCTOR LTD., Migdal Haemek (IL)

(21) Appl. No.: 19/394,599

(22) Filed: Nov. 19, 2025

(30) Foreign Application Priority Data
Nov. 29, 2024 (JP) 2024-208169

(51) Int. Cl. H10F 39/00; H10F 39/18

(52) U.S. Cl. CPC H10F 39/806; H10F 39/182

(57) ABSTRACT

A solid-state imaging device includes a plurality of pixels formed on a silicon substrate. Each pixel includes: a photoelectric conversion region formed in a surface portion of the silicon substrate; an uneven pattern including a recess and a protrusion, provided on a surface of the silicon substrate in the photoelectric conversion region; a first material film that covers a side surface of the uneven pattern, a bottom surface of the recess, and a top surface of the protrusion, while leaving a void in the recess; and a second material film that fills the void. The first material film has a refractive index higher than that of the second material film, and the refractive indices of the first material film and the second material film are both 1.7 or less.

### ROSS-REFERENCE TO RELATED APPLICATION

This application claims priority to Japanese Patent Application No. 2024-208169 filed on Nov. 29, 2024, the entire disclosure of which is incorporated by reference herein.

### BACKGROUND

In various devices such as smartphones, an image sensor (solid-state imaging device) is used to capture images. To improve the light receiving sensitivity of such a solid-state imaging device, the reflectance on a surface of a silicon (Si) substrate used as a semiconductor substrate is reduced to increase the quantum efficiency.

To realize this, it has been known to form an uneven pattern on the surface of the Si substrate. The uneven pattern can pseudo-reduce the refractive index near the surface of the Si substrate, consequently reducing the reflectance. Examples of documents in this field include Japanese Unexamined Patent Publication No. 2020-061576.

### SUMMARY

When an uneven pattern is formed on a surface of a Si substrate, the reflectance can be reduced; however, the electric charge state on the surface of the Si substrate becomes unstable, leading to an increase in dark current. In addition, light transmitted through the uneven pattern tends to be scattered due to diffraction and/or refraction. The scattered light may enter adjacent pixels, causing color mixing, leading to degradation in the quality of a captured image.

The following describes a solid-state imaging device capable of reducing the reflectance of a surface portion of a Si substrate while reducing increases in dark current and light scattering.

A solid-state imaging device of the present disclosure includes a plurality of pixels formed on a silicon substrate. Each of the plurality of pixels includes: a photoelectric conversion region formed in a surface portion of the silicon substrate; an uneven pattern provided on a surface of the silicon substrate in the photoelectric conversion region, the uneven pattern including a recess and a protrusion; a first material film that covers a side surface of the uneven pattern, a bottom surface of the recess, and a top surface of the protrusion, while leaving a void in the recess; and a second material film that fills the void. The first material film has a refractive index higher than that of the second material film, and the refractive indices of the first material film and the second material film are both 1.7 or less.

According to the solid-state imaging device of the present disclosure, the reflectance on the surface of the Si substrate can be reduced while reducing increases in dark current and light scattering.

### BRIEF DESCRIPTION OF THE DRAWINGS

FIG. 1 is a schematic sectional view of a solid-state imaging device of the present disclosure.

FIG. 2 is a schematic plan view of an uneven pattern portion in the solid-state imaging device of the present disclosure.

FIG. 3 is a schematic enlarged sectional view of the uneven pattern portion and its vicinity in the solid-state imaging device of the present disclosure.

FIG. 4 is a schematic sectional view of a solid-state imaging device of a comparative example.

FIG. 5 is a diagram illustrating a case where recesses in the solid-state imaging device of the present disclosure have a relatively large width.

FIG. 6 is a diagram illustrating a case where the recesses in the solid-state imaging device of the present disclosure have a relatively small width.

FIG. 7 is a schematic plan view of another example of the uneven pattern portion in the solid-state imaging device of the present disclosure.

FIG. 8 is a diagram showing the reflectance as a function of the wavelength of incident light for the solid-state imaging device of the present disclosure and the solid-state imaging device of the comparative example.

FIG. 9 is a diagram showing the relationship between the recess area ratio and the reflectance of an antireflection layer 22 for light of different wavelengths.

FIG. 10 is a diagram showing an example of the recess area ratios of the respective colors of color filters arranged in a Bayer pattern in the solid-state imaging device of the present disclosure.

### DETAILED DESCRIPTION

The following describes embodiments of the present disclosure with reference to the drawings. The following description is illustrative and is not intended to be limiting. Various modifications can be made as appropriate, provided that the effects of the present disclosure are obtained.

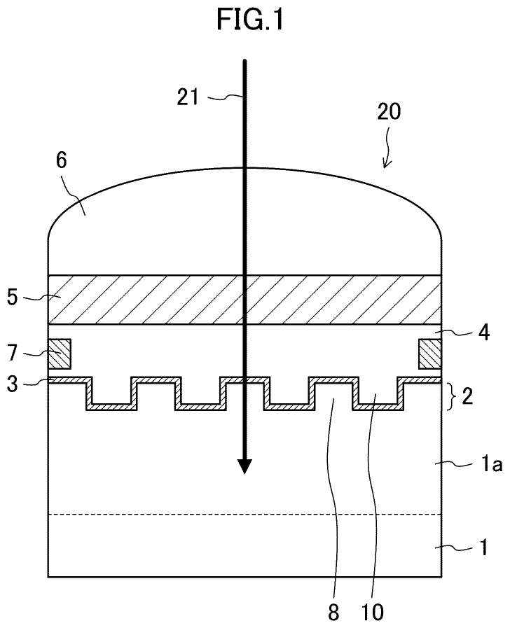

FIG. 1 is a schematic sectional view of a solid-state imaging device 20 (image sensor) of the present embodiment, illustrating a region corresponding to one of a plurality of pixels included in the device.

The solid-state imaging device 20 is a back-illuminated solid-state imaging device configured using a silicon (Si) substrate 1. The silicon substrate 1 has a photodiode structure in which a p-type layer 1a is formed on an n-type layer. This allows the substrate to function as a photoelectric conversion region that converts incident light into electric charges.

An uneven pattern portion 2 including protrusions 8 and recesses 10 is provided on a surface portion of the silicon substrate 1. A fixed-charge film 3, which is a first material film, is formed on a surface of the uneven pattern portion 2, and an oxide film 4 (silicon oxide film), which is a second material film, is formed on the fixed-charge film 3. More specifically, the fixed-charge film 3 is formed so as to cover the side surfaces of the uneven pattern portion 2, the bottom surfaces of the recesses 10, and the top surfaces of the protrusions 8 at a similar thickness. The fixed-charge film 3 does not completely fill the recesses 10, leaving voids therein. The oxide film 4 is formed on the fixed-charge film 3 so as to fill the voids.

In a process of manufacturing the solid-state imaging device 20, the silicon substrate 1 is processed by etching or the like. At this time, the surface of the silicon substrate 1 is damaged, which destabilizes the state of the interface with the film formed on the substrate. In this regard, the state of the interface can be stabilized by forming a film having fixed charges such as Al₂O₃ on the surface of the silicon substrate 1.

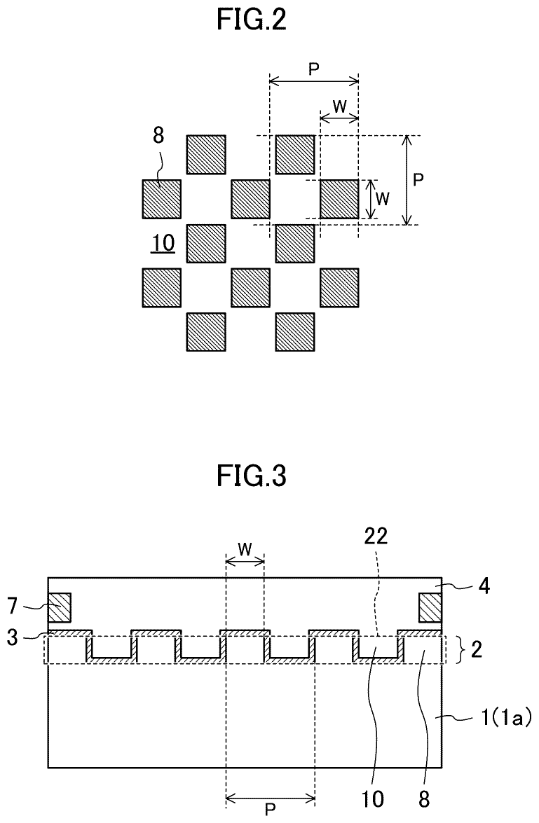

FIG. 2 is a plan view of the uneven pattern portion 2. In the present embodiment, the protrusions 8 are independent, square-shaped, and separated from each other by the recesses 10. The protrusions 8 have a width W and are arranged in a two-dimensional array. An arrangement period P (the sum of the width W and the spacing between adjacent protrusions 8) is the same in the two arrangement directions. The period P is slightly greater than twice the width W in the example of FIG. 2. The rows of the protrusions 8 are arranged so that the positions of the protrusions 8 in adjacent rows do not overlap.

It is most preferable that the side surfaces of the protrusions 8 are perpendicular to the surface of the silicon substrate 1 (the bottom surfaces of the recesses 10). However, such perpendicular side surfaces are not essential to exhibit the effects of the present embodiment. That is, the side surfaces of the protrusions 8 may be inclined to form tapered shapes. For example, the angle of the side surfaces of the protrusions 8 is preferably 30 degrees or less, and more preferably 15 degrees or less, with respect to a plane perpendicular to the surface of the silicon substrate 1.

A color filter 5 and a microlens portion 6 are formed on the oxide film 4. Furthermore, a light-shielding film 7 is formed in the oxide film 4 and between adjacent pixels.

Incident light 21 to the solid-state imaging device 20 passes through the microlens portion 6, the color filter 5, the oxide film 4, and the uneven pattern portion 2, reaches the silicon substrate 1, and is photoelectrically converted. If incident light leaks into an adjacent pixel, color mixing occurs. To reduce this, the light-shielding film 7 is provided. The light-shielding film 7 is formed from a material with high light-shielding properties, such as tungsten (W). The color filter 5 allows light of a target wavelength band for each pixel to pass, to enable the capture of a color image. Therefore, the color filter 5 is not provided in a monochrome image sensor.

FIG. 3 is a diagram showing the uneven pattern portion 2 and its vicinity shown in FIG. 1. In the solid-state imaging device 20 of the present embodiment, the uneven pattern portion 2 is provided on the surface portion of the silicon substrate 1, and the recesses 10 are filled with the fixed-charge film 3 and the oxide film 4. This reduces the effective refractive index of the region surrounded by broken lines, allowing the region to function as an antireflection layer 22.

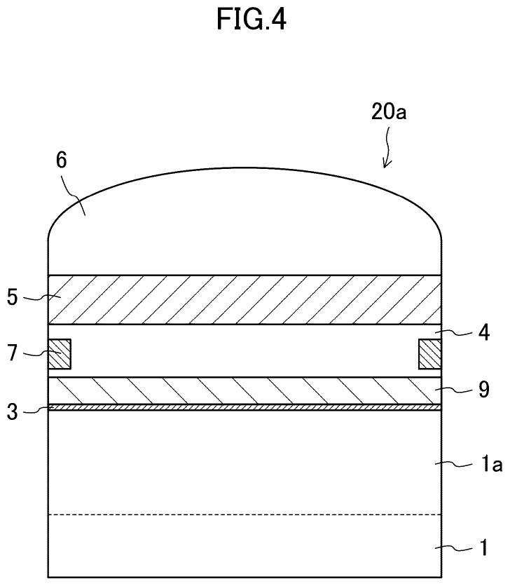

In this regard, FIG. 4 shows a solid-state imaging device 20a of a comparative example. The silicon substrate 1 of the solid-state imaging device 20a has a flat surface portion. The fixed-charge film 3 is formed so as to cover the flat top surface of the silicon substrate 1, and an antireflection film 9 is formed on the fixed-charge film 3. On the antireflection film 9, the oxide film 4, the color filter 5, and the microlens portion 6 are formed as in the solid-state imaging device 20 of the present embodiment.

In the solid-state imaging device 20a of the comparative example, Si₃N₄ (refractive index: 1.94 to 2.05), Ta₂O₅ (refractive index: 2.17), or the like is often used as the antireflection film 9. Note that the refractive indices are measured at a wavelength of 450 nm.

However, since silicon has a high refractive index in the blue-to-green light region (particularly in the blue light region), the refractive index of the antireflection film 9 becomes too low in comparison, making it difficult to practically reduce reflection. For example, when the incident light is blue light (wavelength: 450 nm), it is desired to provide the antireflection film 9 having a refractive index of 2.74 or more, with respect to the silicon (Si) substrate 1 having a refractive index of 4.67. However, no film forming material for semiconductors that meets the above requirement has been known. In addition, in the solid-state imaging device 20a of the comparative example, the fixed-charge film 3 having a low refractive index is formed below the antireflection film 9, and this further reduces the antireflection effect.

In contrast, in the solid-state imaging device 20 of the present embodiment, the antireflection layer 22 having a reduced effective refractive index is realized by providing the uneven pattern portion 2 on the surface portion of the silicon substrate 1 and by filling the recesses 10 with the fixed-charge film 3 and the oxide film 4 each having a refractive index lower than that of the silicon substrate 1.

The effect of reducing the reflectance by the antireflection layer 22 is maximized when the effective refractive index of the antireflection layer 22 is equal to the geometric mean of the refractive indices of the layers above and below the antireflection layer 22, i.e., the geometric mean of the refractive indices of the silicon substrate 1 and the oxide film 4. Accordingly, when the refractive index of Si constituting the silicon substrate 1 is nₛᵢ and the refractive index of the silicon oxide film constituting the oxide film 4 is n_{SiO}, the target value of the effective refractive index of the antireflection layer 22 can be expressed by the following formula (1).

$$Target value of effective refractive index of antireflection layer 22 \approx √ ( {n}_{si} \times {n}_{SiO} ) \qquad ( 1 )$$

Based on the formula (1), the effective refractive index of the antireflection layer 22 is preferably on the order of 2.37 to 2.8 to reduce the reflectance in the visible region (wavelengths of approximately 400 nm to 650 nm) close to zero.

This can be achieved by using a material, to fill the recesses 10, having a refractive index lower than the target value of the effective refractive index. In particular, it is desirable to use a material having a refractive index of 1.7 or less. Specific examples of such a material include Al₂O₃, which has a refractive index of 1.6, and SiO₂, which has a refractive index of 1.46.

The effective refractive index of the antireflection layer 22 is calculated as a weighted average of the refractive indices of the protrusions 8 and the recesses 10, using their respective volume ratios as weights. That is, the effective refractive index is obtained by adding the product of the refractive index of the recesses 10 and the volume ratio of the recesses 10 to the product of the refractive index of the protrusions 8 and the volume ratio of the protrusions 8. For example, when the volume ratios of the protrusions 8 and the recesses 10 are 40% and 60%, respectively, the refractive index of the protrusions 8 is 4.67, and the refractive index of the recesses 10 is 1.47, the effective refractive index of the antireflection layer 22 is calculated as follows: 4.67×0.4+1.47×0.6=2.75.

Thus, a desirable recess area ratio is determined from: the material of the protrusions 8 and the material filling the recesses 10; and the target value of the effective refractive index.

Furthermore, it is desirable to design the uneven pattern portion 2 with respect to dark current in addition to the characteristics as the antireflection layer 22.

The formation of the uneven pattern portion 2 on the surface portion of the silicon substrate 1 may destabilize the electric charge state on the surface of the silicon substrate 1, increasing the dark current. The dark current may deteriorate the image quality. In particular, the dark current tends to cause a dark image to appear white and blurred.

The dark current increases or decreases in proportion to the surface area of the recesses 10. Thus, an increase in the dark current can be reduced by reducing the surface area of the recesses 10. For this purpose, it is preferable to decrease the refractive index of the material filling the recesses 10. The volume ratio of the recesses 10 required to achieve the desired refractive index of the antireflection layer 22 can be reduced by filling the recesses 10 with a material having a lower refractive index. As a result, the surface area of the recesses 10 is reduced, and thus an increase in the dark current can be reduced.

Furthermore, filling the recesses 10 with a material having a low refractive index is also effective to reduce color mixing between pixels. One of the causes of color mixing is scattering occurring when light passes through the uneven pattern portion 2. To reduce the scattering of the transmitted light, it is effective to reduce the period P (see FIGS. 2 and 3) of the uneven pattern portion 2. More specifically, by setting an effective period P_{E} calculated by taking the refractive index into account to be smaller than the wavelength of the transmitted light, diffraction of light can be reduced, and thus scattering can be reduced. As a result, color mixing can be reduced.

The effective period P_{E} calculated by taking the refractive index into account is obtained by summing up the products of the respective dimensions and the refractive indices of the protrusions 8 and the recesses 10. For example, when the width of the protrusions 8 made of Si having a refractive index of 4.67 is 75 nm and the width of the recesses 10 filled with SiO₂ having a refractive index of 1.47 is 95 nm, the effective period P_{E} is obtained as follows: Effective period P_{E}=4.67×75 nm+1.47×95 nm=490 nm.

Therefore, if the dimensions of the protrusions 8 and the recesses 10 (and the period P) are the same, the effective period P_{E} decreases as the refractive index of the material filling the recesses 10 decreases, and consequently, scattering of incident light and color mixing are reduced.

As described above, the desirable recess area ratio is determined from the target value of the effective refractive index of the antireflection layer 22. If the recess area ratio is unchanged, the period P is reduced by reducing the width W of the protrusions 8, and as a result, the effective period P_{E} is also reduced. However, since the minimum width of the protrusions 8 that can be practically formed depends on the processing means, it is difficult to freely reduce the width W and the period P. When an immersion ArF exposure system is used, for example, the minimum processable width is considered to be approximately 75 nm. However, the technique of the present disclosure is not limited to this dimensional example.

In the solid-state imaging device 20 of the present embodiment, the fixed-charge film 3 covering the surface of the uneven pattern portion 2 is provided. Due to the presence of the fixed-charge film 3, it is possible to stabilize the electric charges on the surface of the silicon substrate 1, reducing the dark current. Since the fixed-charge film 3 also partially fills the recesses 10, it is desirable that the fixed-charge film 3 has a low refractive index. Therefore, it is desirable to use, for example, Al₂O₃ with a refractive index of 1.6 as a material of the fixed-charge film 3. As a material of a fixed-charge film, Al₂O₃ is one of materials having significantly low refractive indices.

However, in order to exhibit the above-described effect, the fixed-charge film 3 preferably has a predetermined thickness. For example, the film thickness is preferably 15 nm or more. On the other hand, as for the materials filling the recesses 10, it is preferable to increase the ratio of SiO_{2,} which has a lower refractive index than Al₂O₃. From this viewpoint, there is an upper limit to the preferable film thickness of the fixed-charge film 3. The film thickness is preferably 40 nm or less, for example.

As described above, the fixed-charge film 3 is provided so as not to completely fill the recesses 10, and voids are left within the recesses 10. The oxide film 4 made of SiO₂ having a refractive index of 1.46 is formed on the fixed-charge film 3 so as to fill the voids.

Thus, the fixed-charge film 3 is formed on the silicon substrate 1, and the oxide film 4 is subsequently formed on the fixed-charge film 3. As a result, the refractive indices decrease sequentially. Consequently, the difference between the refractive indices at each interface is reduced, enhancing the antireflection effect.

To form the uneven pattern portion 2, for example, a resist pattern is formed on the surface of the silicon substrate 1 through an exposure process using an immersion ArF exposure system, and subsequently, dry etching is performed. Thus, the surface of the silicon substrate 1 is etched in accordance with a predetermined pattern to form the recesses 10, and the remaining portions serve as the protrusions 8.

In the example of the present embodiment, the period P of the pattern is 170 nm, and the width of the protrusions 8 (i.e., one side of the square) is 75 nm. The height of the protrusions 8 is 55 nm. The height of the protrusions 8 (in other words, the depth of the recesses 10) is preferably 40 nm or more, from the viewpoint of ensuring the antireflection effect in the green to red wavelength region. The height is preferably 40 nm or more, also from the viewpoint of clearly defining the shape of the protrusions 8. On the other hand, the height of the protrusions 8 is preferably 70 nm or less from the viewpoint of ensuring the antireflection effect in the blue region and reducing the generation of diffracted light.

In the example of the present embodiment, the area ratio of the etched recesses 10 is approximately 63%. That is, in the plan view of FIG. 2, the ratio of the area occupied by the recesses 10 to the total area of the protrusions and the recesses 10 is approximately 63%.

In the present embodiment, the use of Al₂O₃ and SiO₂ having low refractive indices as the materials filling the recesses 10 can reduce the recess area ratio to 63% while achieving a desirable effective refractive index of the antireflection layer 22. The following shows examples of recess area ratios required to achieve a desirable effective refractive index of the antireflection layer 22 when other materials are used to fill the recesses 10.
Al₂O₃ only: 67%
HfO+SiO₂: 67%
ZrO+SiO₂: 70%

Thus, by using materials having low refractive indices to fill the recesses 10, it is possible to reduce the area ratio of the recesses 10 formed by etching the silicon substrate 1 and to reduce an increase in the dark current due to the formation of the uneven pattern portion 2.

Next, optical effects will be described.

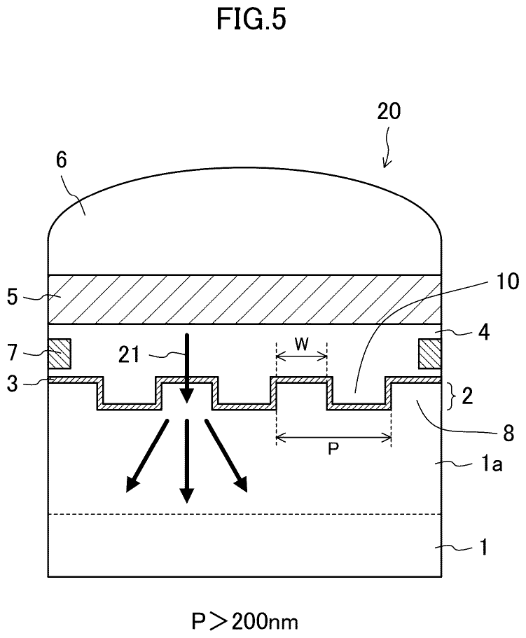

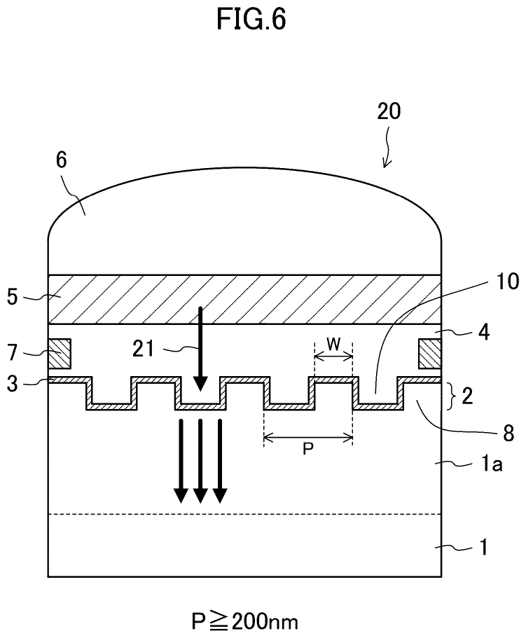

FIGS. 5 and 6 are diagrams for comparing the state of light scattering after transmission through the uneven pattern portion 2 in the solid-state imaging devices 20 of the present embodiment, which have different periods P of the uneven pattern portion 2.

In FIG. 5, the width W of the protrusions 8 is 100 nm. When the recess area ratio is 63%, the period P is determined as 227 nm. In this case, incident light 21 transmitted through the uneven pattern portion 2 is scattered due to diffraction. Scattering due to diffraction is more likely to occur as the width W and the period P increase. It is desirable to reduce light scattering, as it may cause color mixing in adjacent pixels.

In contrast, FIG. 6 shows the device with the dimensions described with reference to FIGS. 1 to 3. That is, the period P is 170 nm, and the width W is 75 nm. In this case, incident light 21 is less likely to be scattered due to diffraction even after being transmitted through the uneven pattern portion 2. Thus, by setting the period P and the width W as above, scattering of incident light 21 can be reduced, and as a result, color mixing can be reduced.

To reduce scattering due to diffraction, the period P is desirably 200 nm or less. In this case, when the recess area ratio is 63%, the width W is determined as 90 nm. Based on this, the width W is preferably 90 nm or less. However, even when the period P exceeds 200 nm, the effect of reducing the reflection of incident light can be provided by the antireflection layer 22.

In the above example, the shape of the protrusions 8 in a plan view is a square, as shown in FIG. 2. This allows the protrusions 8 to be arranged most densely in both horizontal and vertical directions in FIG. 2.

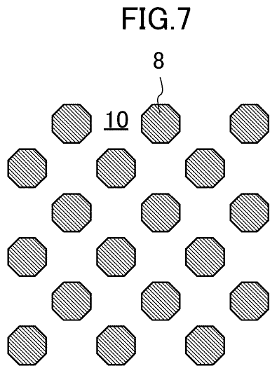

In contrast, FIG. 7 shows another example in which the protrusions 8 have a regular octagonal shape when viewed from a direction perpendicular to the silicon substrate, that is, in a plan view. In this configuration, the spacing between the protrusions 8 can be reduced also in an oblique direction, allowing the protrusions 8 to be densely arranged.

When the area ratio of the recesses 10 is set to the same value of 63% in both the configurations of FIG. 2 and FIG. 7, the antireflection effect of the uneven pattern portion 2 is similar in these configurations. However, the spacing between the protrusions 8 can be reduced in the configuration of FIG. 7, which increases the effect of reducing light scattering.

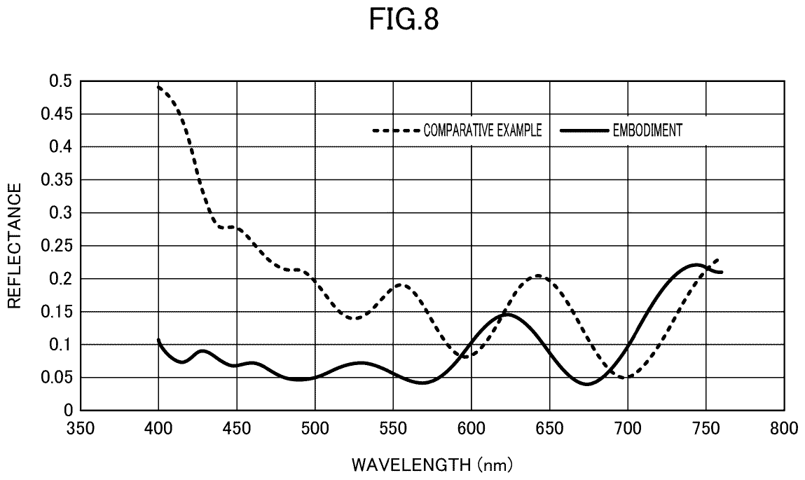

FIG. 8 shows measurement results of the reflectance as a function of the wavelength of incident light for each of the solid-state imaging device 20 of the present embodiment and the solid-state imaging device 20a (FIG. 4) of the comparative example. It should be noted that each of the devices is a monochrome imaging device including no color filter 5. In the device of the comparative example, Si₃N₄ having a refractive index of 1.95 was used as the antireflection film 9.

As shown in FIG. 8, the reflectance of the embodiment is lower than the reflectance of the comparative example in most of the wavelength bands. In particular, the reflectance is remarkably low in the wavelength range from the blue region at 400 nm to the yellow region at 570 nm.

Although FIG. 8 shows an example using the monochrome imaging devices, a color imaging device including a color filter 5 can be optimized by changing the recess area ratio for each color.

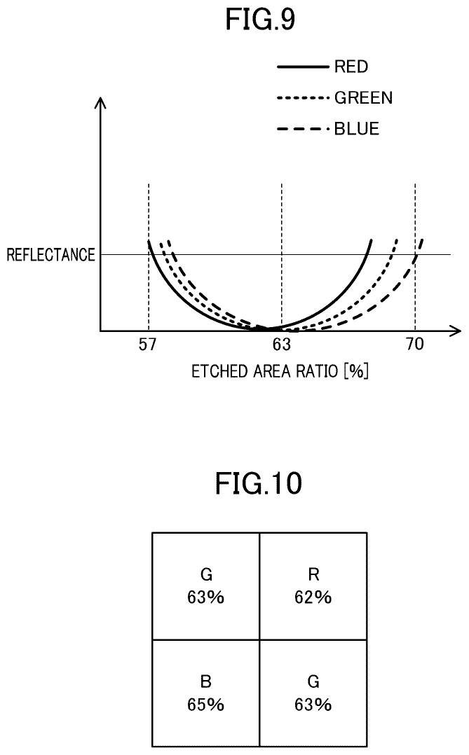

FIG. 9 shows the relationship between the recess area ratio and the reflectance of the antireflection layer 22 for light of different wavelengths. To be more specific, the figure shows the relationship for blue light (wavelength 450 nm, indicated by a broken line), green light (wavelength 530 nm, indicated by a dotted line), and red light (wavelength 600 nm, indicated by a solid line).

As shown in FIG. 9, the recess area ratio desirable to reduce the reflectance varies depending on the wavelength. The area ratio of the recesses 10 at which the reflectance is minimized (i.e., optimal) and the range of the area ratio in which the reflectance is lower than that of the solid-state imaging device 20a of the comparative example (i.e., improved compared to the comparative example) are as follows.
Blue: optimal at 65%, improved in the range of 60% or more and 70% or less
Green: optimal at 63%, improved in the range of 58% or more and 68% or less
Red: optimal at 62%, improved in the range of 57% or more and 67% or less

Thus, the longer the wavelength of light, the lower the desired area ratio. Furthermore, as for visible light, it can be said that the reflectance is improved when the area ratio is 57% or more and 70% or less.

It should be noted that light is not limited to blue, green, and red. When a first pixel for receiving light of a first wavelength and a second pixel for receiving light of a wavelength longer than the first wavelength are included, it is preferable that the ratio of the area occupied by the recesses in the uneven pattern in the first pixel is larger than the ratio of the area occupied by the recesses in the uneven pattern in the second pixel.

In a color solid-state imaging device 20, the reflectance for each color can be optimized (the quantum efficiency can be maximized) by applying the above-described optimal recess area ratios to the photoelectric conversion regions respectively corresponding to the colors. For example, in the example of FIG. 10, blue (B), green (G), and red (R) color filters are arranged in a Bayer pattern, and for each color, the recess area ratio of the uneven pattern portion 2 provided on the silicon substrate 1 is set to the above-described optimal value.

Although the back-illuminated solid-state imaging device has been described above as an example, similar effects can be obtained also in a front-illuminated solid-state imaging device.

As described above, according to the solid-state imaging device of the present disclosure, the reflectance of the surface portion of the silicon substrate 1 can be reduced, and an increase in dark current can be reduced. Furthermore, the period P of the uneven pattern portion 2 provided on the silicon substrate 1 can be reduced, to reduce the generation of diffracted light and scattered light, reducing color mixing in adjacent pixels. Accordingly, the image quality of a captured image can be improved.

The embodiments described above can be modified in form and detail without departing from the spirit of the claims. The contents of each embodiment can be combined and replaced as appropriate as long as the functions of the subject of the disclosure are not impaired.

The solid-state imaging device of the present disclosure is useful as an imaging device in various cameras, portable devices, and the like.

What is claimed is:

1. A solid-state imaging device including a plurality of pixels formed on a silicon substrate,
each of the plurality of pixels comprising:
a photoelectric conversion region formed in a surface portion of the silicon substrate;
an uneven pattern provided on a surface of the silicon substrate in the photoelectric conversion region, the uneven pattern including a recess and a protrusion;
a first material film that covers a side surface of the uneven pattern, a bottom surface of the recess, and a top surface of the protrusion, while leaving a void in the recess; and
a second material film that fills the void,
the first material film having a refractive index higher than that of the second material film,
the refractive indices of the first material film and the second material film being both 1.7 or less.

2. The solid-state imaging device of claim 1, wherein
the first material film covers the side surface of the uneven pattern, the bottom surface of the recess, and the top surface of the protrusion at a similar thickness.

3. The solid-state imaging device of claim 1, wherein
the first material film is a fixed-charge film.

4. The solid-state imaging device of claim 3, wherein
the fixed-charge film has a film thickness of 15 nm or more.

5. The solid-state imaging device of claim 3, wherein
the fixed-charge film is made of Al₂O₃.

6. The solid-state imaging device of claim 1, wherein
a ratio of an area occupied by the recess in the uneven pattern is 57% or more and 70% or less.

7. The solid-state imaging device of claim 1, wherein
the protrusion has a width of 90 nm or less.

8. The solid-state imaging device of claim 1, wherein
the recess in the uneven pattern has a depth of 40 nm or more and 70 nm or less.

9. The solid-state imaging device of claim 1, wherein
the plurality of pixels include
a first pixel configured to receive light of a first wavelength; and
a second pixel configured to receive light of a wavelength longer than the first wavelength, and
a ratio of an area occupied by the recess in the uneven pattern in the first pixel is larger than a ratio of an area occupied by the recess in the uneven pattern in the second pixel.

10. The solid-state imaging device of claim 1, wherein
the plurality of pixels include
a blue pixel configured to receive blue light,
a green pixel configured to receive green light, and
a red pixel configured to receive red light, and
a ratio of an area occupied by the recess in the uneven pattern is 60% or more and 70% or less in the blue pixel, 58% or more and 68% or less in the green pixel, and 57% or more and 67% or less in the red pixel.

11. The solid-state imaging device of claim 1, wherein
the protrusion has an octagonal shape when viewed from a direction perpendicular to the silicon substrate and has a width of 90 nm or less.

12. The solid-state imaging device of claim 1, wherein
a side surface of the protrusion is at an angle of 30 degrees or less with respect to a plane perpendicular to the surface of the silicon substrate.
